(19) United States
(12) Patent Application Publication
(10) Pub. No.: US 2008/0308884 A1
(43) Pub. Date: Dec. 18, 2008

(54) Fabrication of Inlet and Outlet Connections for Microfluidic Chips

(75) Inventor: Edvard Kalvesten, Hagersten (SE)

Correspondence Address: YOUNG & THOMPSON, 209 Madison Street, Suite 500, ALEXANDRIA, VA, 22314, US

(73) Assignee: SILEX MICROSYSTEMS AB, JARFALLA (SE)

(21) Appl. No.: 12/090,096

(22) PCT Filed: Oct. 5, 2006
(86) PCT No.: PCT/SE2006/050381

§ 371 Date: Apr. 14, 2008

(30) Foreign Application Priority Data
Oct. 13, 2005 (SE) 0502288-4

(51) Int. Cl. H01L 29/00; H01L 21/00

(52) U.S. Cl. 257/414; 438/49; 257/E29.001; 257/E21.001

(57) ABSTRACT

A method of making a fluid communication channel between a micro mechanical structure provided on a front side of a device and the back side of said device is described. It includes making the required structural components by lithographic and etching processes on said front side. Holes are then drilled from the back side of said device in precise alignment with the structures on said front side, to provide inlets and/or outlets to and/or from the micromechanical structure.

The invention relates to methods of providing fluid communication between opposite sides of microfluidic chips. In particular it relates to a fabrication method that increase yield and cut fabrication costs of produced chips.

### BACKGROUND OF THE INVENTION

In the manufacture of semiconductor microstructures such as micro-fluidic chips for e.g. biological and/or chemical analysis, it is often required to provide fluid connection between front and back sides of the chips. Conventional manufacturing technology entails various oxidation, deposition, lithographic and etching procedures in order to make the required functional structures.

The starting material is commonly silicon wafers (100, 150, 200 or 300 mm diameter). To fabricate microstructures within such wafers different etching methods are used to remove silicon on selected areas defined by photo lithography methods. Both wet silicon etches such as KOH, TMAH, EDP etc and dry plasma etches (for example DRIE) may be used to etch micro structures wafer through interconnections. To be able to perform the etching a masking material is needed. The masking material will not be affected by the Si etchant. The most commonly used masking material for silicon etching is silicon oxide (SiO₂). Hence, the silicon wafers are subjected to a first oxidation step where the entire surface is covered by a SiO₂ layer. However, because the wafers are positioned in boat “racks” of various kinds during oxidation, the points of contact (normally the wafer edge) will become “deficient” in the oxide coverage at such points. Also the lithography process used may result in poor coverage of resist on wafer edges. In subsequent steps such as etching etc. it often happens that the parts of wafers (normally the edges) not covered with masking material will be etched with the result that very minute particles come off the wafer from these points of deficiency. Such particles may decrease the yield in further lithography and etching steps later on in process. Further, automated handling of wafers using robots of various kind may cause problems due to the defects on wafer edge after the silicon have been etched for a longer time.

### SUMMARY OF THE INVENTION

In view of the drawbacks indicated above, the present invention sets out to provide a method of fabricating e.g. micro fluidic chips, wherein the yield rate can be substantially increased, preferably close to the 100% level.

This object is achieved with the method defined in claim 1.

Thus, the invention relates to a method of making a fluid communication channel between a micro mechanical structure provided on a front side of a device and the back side of said device, comprising making the required structural components by lithographic and etching processes on said front side; drilling holes from the back side of said device in precise alignment with the structures on said front side, to provide inlets and/or outlets to and/or from said micromechanical structure.

The term “drilling” as used herein is taken to mean any process or method usable for creating holes in any material used for making devices using the method according to the invention. It may include, but is not limited to, Drilling, Laser drilling, Ultra sonic drilling, Water or sand power blasting, Electro Discharge Machining (EDM micromachining), etc for the purpose of forming inlets and/or outlets (wafer through connections from the backside to the frontside) to or from the micro mechanical structures made.

Further scope of applicability of the present invention will become apparent from the detailed description given hereinafter and the accompanying drawings which are given by way of illustration only, and thus not to be considered limiting on the present invention, and wherein

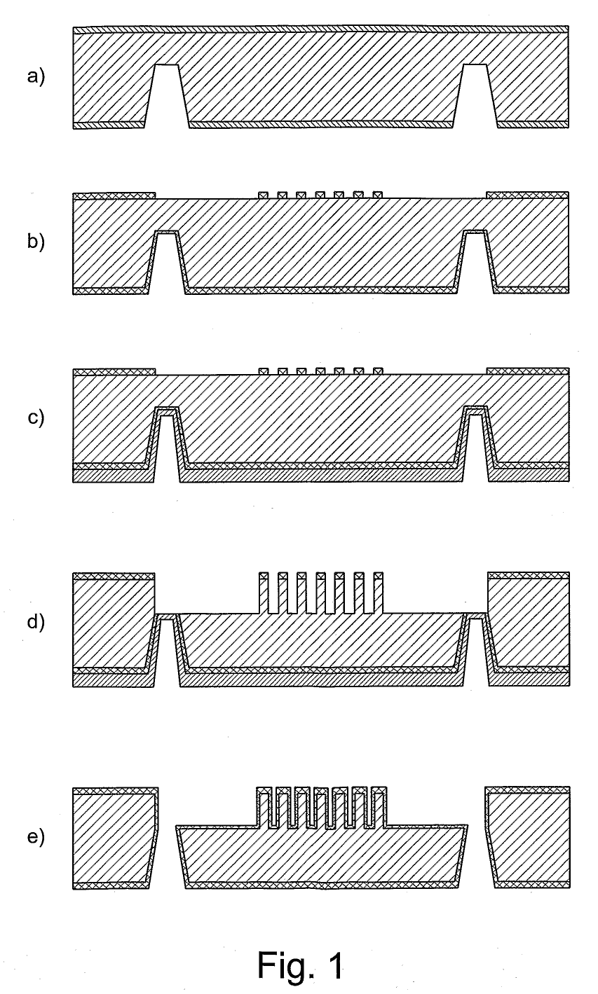

FIG. 1 shows one prior art process;

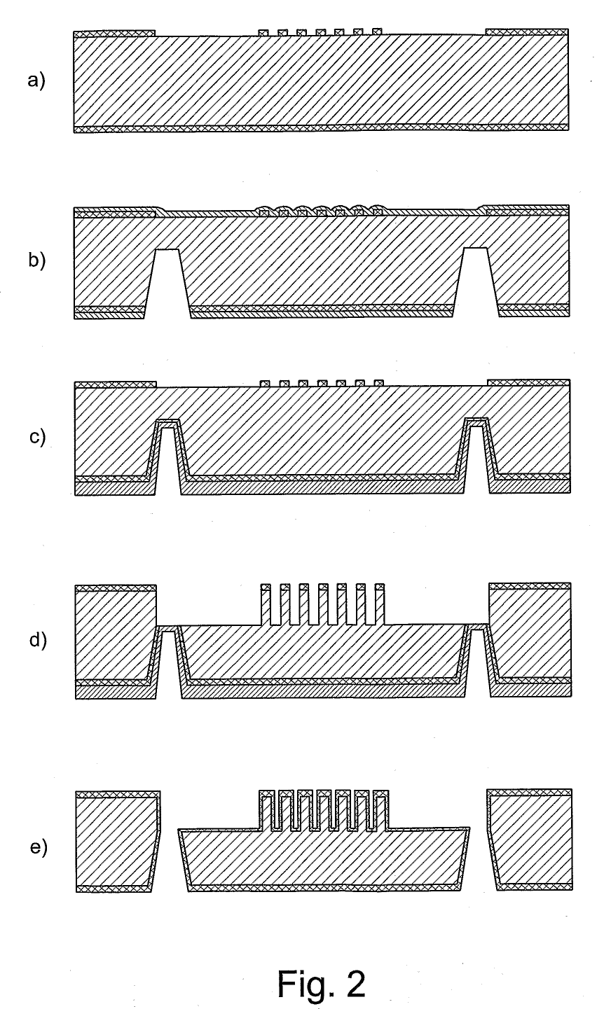

FIG. 2 shows another prior art process; and

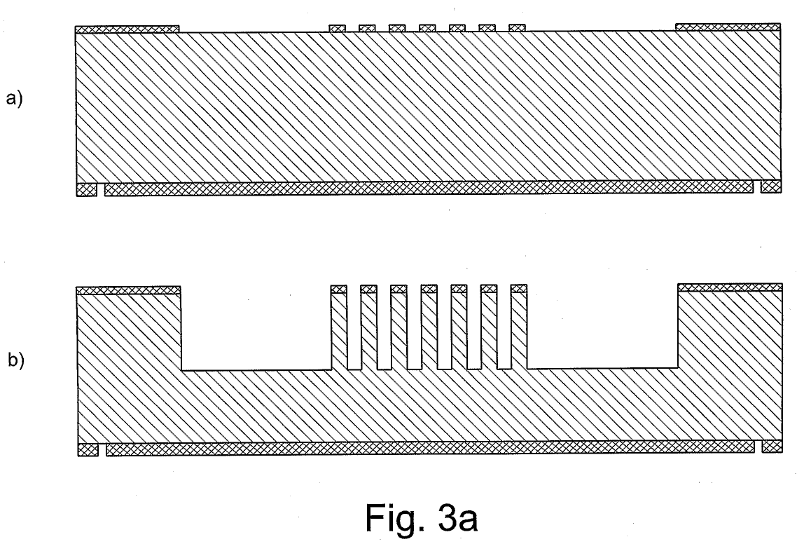

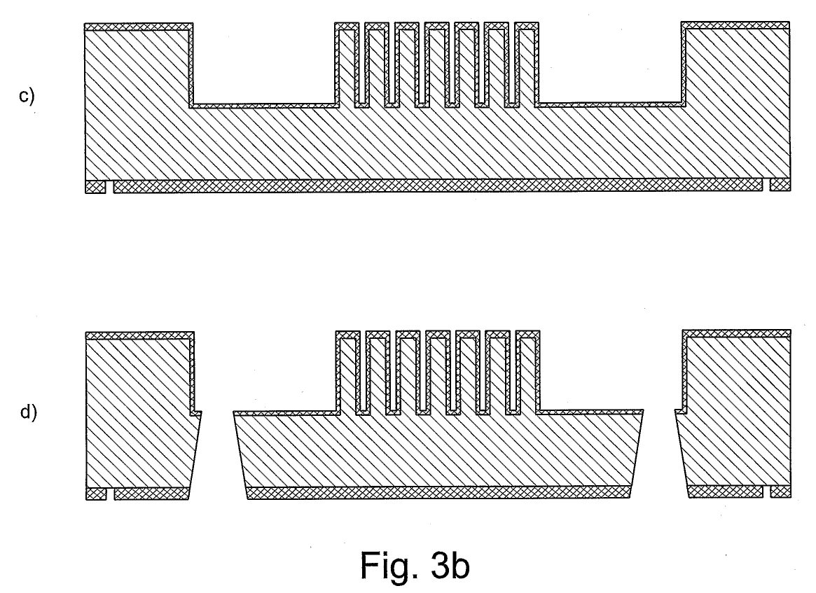

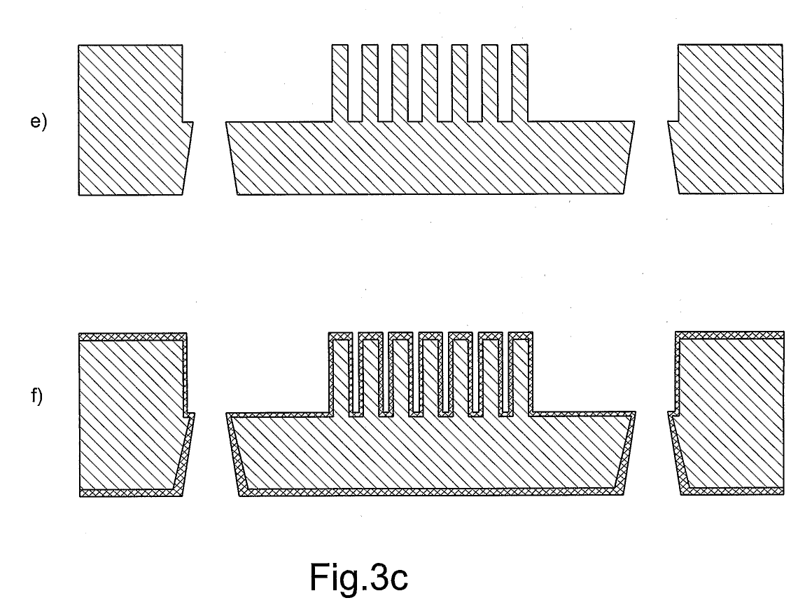

FIGS. 3a-c illustrate the present invention.

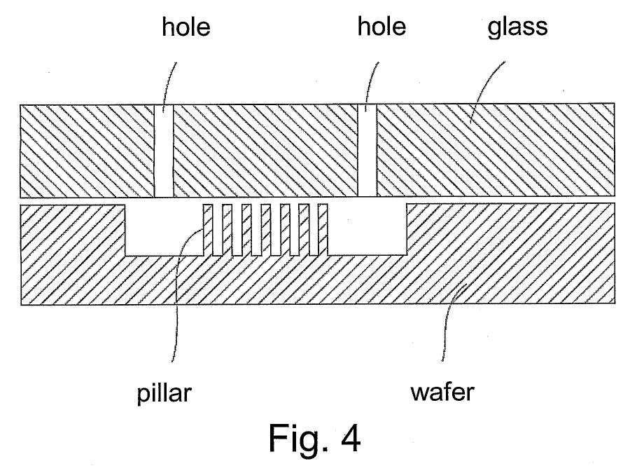

FIG. 4 illustrates a further embodiment of the invention.

### DETAILED DESCRIPTION OF PREFERRED EMBODIMENTS

With reference to FIG. 1 a prior art method will now be described.

The process comprises a number of steps, indicated as a)- e). In the first step a), pyramidal hole structures are made by lithography and etching through low-stress nitride deposited on the entire wafer. V-grooves are etched in KOH. The depth should be equal to wafer thickness minus pillar height. Next, in step b), nitride is removed and the wafer is thermally oxidized. The oxide layer is patterned and plasma etched on the front side to provide the pattern defining the desired structures. Thermal oxidation of the wafer. The thickness of the thermal oxide has to be thick enough to work as a DRIE mask later in the process. Oxide layer is patterned and plasma etched on the front side. In step c) aluminium is sputtered onto the back side to protect the pyramidal hole structures. Al is thereby used as a thin protective membrane so as not to obtain a hole through the wafers. Wafers with through-holes destroy the chucks on which the wafers rest in the DRIE machines, and renders certain robotic manipulation impossible, in particular where the wafers are sucked by applying a vacuum to the back side. The pillars are DRIE etched. The KOH etched grooves should be ceep enough to be opened during the DRIE process, which is made from the front side. Step d) involves DRIE etch applied to form pillars (or “micro posts”). Finally, i.a. Al and thermal oxide is removed in step e), and a final 500 Å thick thermal oxide layer is provided on the entire wafer before dicing. The wafers are carefully cleaned from possible passivation (from DRIE), aluminium and thermal oxide. A final thermal oxidation of 500 Å is performed before the wafer is diced.

In essence, the problem is that one looses yield in the maufacture. Particles coming from frayed edges of the wafers due to etching will result in the following problems:
i) they will cause “masking” such that the desired structure will not become patterned or etched correctly (depending on whether positive or negative resist is used the result will be areas with connected pillar structures, or in the alternative areas without any pillars at all), i.e. lower yield for the product in question.
ii) today Back Side Alignment (BSA) litho machines using projective stepper litho are very rarely used, while BSA machines for 1:1 litho are much more commonly used. In IC manufacturing projecting stepper litho is preferably used, with a spacing between mask and wafer, whereas MEMS manufacturing often requires patterns on both sides of wafer which means that the lithography most often is preformed in a contact mode (e.g 1:1 BSA mode were mask and wafer are brought into contact). With 1:1 contact lithography it is difficult to obtain high resolution patterns (e.g. large arrays of circular pillar structures with <10 μm diameter having sub-μm tolerances) if there are particles present between mask and wafer (or upwards protruding particles from the etched and frayed wafer edge).
iii) robot handling problems of the wafers since the edges are not smooth.
iv) in addition, particles come off from the wafer edges when wafers are transferred between cassettes (and when loading wafers into the “boats” in the furnaces etc). These particles can cause problems impeding the proper functioning of the micro fluidic device in use since the particles can be moved around by the flowing liquids or gases. Thereby the particles can adhere on the pillars in such a way that the desired capillary flow between the pillars become hampered. However, first and foremost the machines were the particles flake off will become contaminated resulting in increased machine down-times as well as decreased yield for actual device in question but also risk for decreased yield for other products processed by the that machine.
v) also, the particle can even destroy the hard ware glass plate mask used in the litho step, by e.g. scratching.

An alternative prior art method is shown in FIG. 2. It differs mainly from the above described method in that the functional structures are defined by patterning (step a) before the pyramidal hole structures are made by wet anisotropic Si etching (KOH etc). The steps of FIG. 2 are as follows:
a) A thermal oxidation of the wafer. The thickness of the thermal oxide has to be thick enough to work as a DRIE mask later in the process.
b) Low-stress nitiride is deposited on the wafer. Backside lithography and etch of bothe low-stress nitride and thermal oxide. V-grooves are etched in KOH. The depth should be equal to wafer thickness-pillar height.
c) The low-stress nitride is fully recovered by wet etching in phosphoric acid. 1000 Å thermal oxide is grown on the wafer before aluminium with a typical thickness of 1 μm is sputtered on the backside. The aluminium will prevent the DRIE plasma to etch through the wafer and destroy the chuck. 1000 Å thermal oxide is removed from the front side with a short plasma etch.
d) The pillar s are DRIE etched. The depth of the KOH etched grooves should be enough to be opened during the DRIE process.
e) The wafers are carefully cleaned from possible passivation (from DRIE), aluminium and thermal oxide. A final thermal oxidation of 1000 Å is performed before the wafer is diced.

Furthermore, there is provided a protective nitride layer before the pyramidal hole structures are made. The advantage with this approach is that the most critical lithography is made before the wafers have been etched (e.g. wafer edges are intact).

A still further method uses DRIE (Dry Reactive Ion Etch) instead of wet KOH etch, which provides for circular holes with almost straight walls. However, also the DRIE methods gives defect wafer edges if the masking material has poor coverage at wafer edge. This is similar to the situation described above for the wet KOH etched in/out lets holes.

Drawbacks with the prior art approaches described above are the following:
Several lithographic steps and film depositions and removals (nitride, oxide, Al etc) are required
KOH etching is time consuming and relative expensive even for batch fabrication with 25 wafers processed at the same time.

Now the novel method according to the invention will be described. First an oxide layer is grown on the starting semiconductor (e.g. silicon) wafer. The layer has to be thick enough to be usable as a DRIE mask for the further processing of the wafer. Suitably the layer is 0.5-4 μm thick. A pattern (hard ware glass plate mask) defining the functional structures (e.g. pillars and channels etc.) is transferred to the oxide by lithographic and etching methods (e.g. photo resist is applied to the surface exposed and a pattern is developed which is used as mask during the etching; (see step a) FIG. 3a in which there is a thermal oxidation of the wafer. The thickness of the thermal oxide has to be thick enough to work as a DRIE mask later in the process. Oxide layer is patterned and etched on both sides of wafer). Also, the back side of the wafer is suitably patterned to provide an alignment pattern for the purpose of enabling the subsequential provision of holes by drilling (described below). Additional “dummy” alignment markings will only be required for alignment of the drilled holes. To the knowledge of the inventors there at present no NSC machines available that can drill wafer through holes from the back-side and align said holes to patterns on the front side. Note that no extra glass mask is required, and instead one can include specific mirror symmetrical alignment marks (fitting against each other on both the front side and the back side) on the front side pillar mask that can be used also as the back side mask. The entire pattern is etched temporarily slightly into the oxide (however, it is only the mirror symmetrical alignment markings that have any function), since the oxide is removed later in the process the pillar mask pattern will not be visible on the back side of the final product, but will function as a temporary dummy alignment marking for the drilling. An etching (suitably a silicon DRIE process) is performed through the mask so as to create the structures forming the micro fluidic chip device, and said alignment pattern (suitably oxide etch process) (see step b) in FIG. 3a in which is shown how the pillars are DRIE etched). The structures in question are the plurality of micro pillars forming the active structure.

When the desired structures on front side (micro pillars) and on the back side (alignment pattern) have been created, a thermal oxidation (typically in wet (or dry) O₂ atmosphere, at 800-1200° C., in a standard semiconductor oxidation oven, 0.5-4 μm thick) of the entire wafer is performed so as to create a protective layer (see step c) in FIG. 3b, in which thermal oxidation is performed before the wafer is “drilled”; purpose: protective layer). The reason is that in the subsequent drilling step (described below), it is most likely that minute particles or chips, created as a consequence of the cutting in the wafer material, will spread in the environment close to the active structures and adhere to the micro pillars. Such particles would be extremely difficult to get rid of if they adhered directly onto the wafer material. When drilling is finished, a “lift-off” process (to be described) is performed, whereby particles will come off together with the oxide layer.

Then, after having provided the protective oxide layer, holes are “drilled” from the back side using any of the methods Drilling, Laser drilling, Ultra sonic drilling, Water or sand power blasting, Electro Discharge Machining (EDM micromachining), although any other method capable of providing holes of a suitable dimension with the desired degree of precision in alignment is possible, so as to form inlets and/or outlets (wafer through connections from the backside to the frontside). The in/out let holes are “drilled” from backside and the drilled holes are aligned against the pre-patterned structures on the backside. The “drilled” hole has inclined or straight walls possible dependent on “drilling” method.

Thus, the process according to the invention is a single wafer process using a serial fabrication method. All these machining steps make use of automated alignment (pattern recognition systems together with Computerized Numerical Control CNC-machines) and automated wafer handling (cassette to cassette robot loadings as in normal semiconductor manufacturing). In contrast to prior art methods where holes are etched and a large number of wafers are processed in one batch, the present method employs a serial manufacturing process, i.e. one wafer at a time is subjected to the drilling procedure. By the use of the drilling method the wafer handling by the robots becomes much easier to achieve with increased yield and up-time for this particular machine and also for all machine(s) to be used later on in the process since the wafer edge will not be damaged during the drilling. Damages to the wafer edge most often occurs when the earlier described prior art method is employed, using the KOH or DRIE etching methods to form the wafer through fluidic interconnections.

After having drilled the holes as described above the protective oxide is etched away. In this process any particles adhering to the active structures (pillars) will come off and be removed together with the oxide, since the oxide present between the particle and the under-laying wafer material will be removed by the etch, and thus the particles will be “loose” and can therefore easily be rinsed away. This is referred to as a “lift-off” process, see e) in FIG. 3c, and entails oxide etch and wafer cleaning (feature: “lift-off” potential drilling residues remaining on wafer. In f) a final thermal oxidation (typically 500 Å) is performed before the wafer is diced and inspected.

Finally, an oxide is grown on the entire wafer to a thickness of 500-1000 Å, before the wafer is diced and inspected.

After having cut the wafer into individual chips, the result is a micro fluidic device comprising structural components on one side of a substrate and at least one inlet and/or outlet to/from said components opening on the back side of said substrate.

The invention offers the following advantages:
It is faster than conventional methods (typically 300 holes per 625 μm thick 6″ wafers takes approx. 1 hour to “laser drill” for a whole a batch of 25 wafers machine by laser cutting).
it is less expensive compared to the KOH or DRIE etching processes that requires several steps of depositing removing different thin film layers (nitride, oxide, Al.), which are not necessary for this approach
improved yield in the manufacture of the micro fluidic product(s) in question
in addition one avoids that particles come off from the wafer edges during transfer of the wafers between cassettes and other machines (loading the wafers into the boats in the oxidation furnaces etc), contaminate and impairs “up-time” and yield, also for other products that are manufactured in the same machine(s), and that particles generally increase down-times and yield for the entire production plant.

For certain applications it is possible to introduce liquid to be analyzed from the front side of a microfluidic device. Thereby a lid (suitably glass) having holes drilled in it is bonded onto the wafer on top of the structures (see FIG. 4).

The advantages of this embodiment is that the holes that are drilled in the glass will not have to be aligned against any other pattern. The holes are drilled only at a predetermined spacing, but the starting point is of no importance. The alignment of holes and pillar structures takes place in the bonding step.

1-7. (canceled)

8. A method of making a fluid communication channel between a micro mechanical structure provided on a front side of a device and the back side of said device, comprising
making the required structural components by lithographic and etching processes on said front side;
drilling holes from the back side of said device in precise alignment with the structures on said front side, to provide inlets and/or outlets to and/or from said micromechanical structure.

9. The method as claimed in claim 8, wherein the step of making the structural components comprises
growing a first oxide layer on a starting semiconductor, e.g. silicon wafer;
transferring a pattern defining the functional structures of the microfluidic device is transferred to the oxide by lithographic and etching methods; and
etching through the mask so as to create the structures forming the micro fluidic chip device, and said alignment pattern;

10. The method as claimed in claim 8, wherein also the back side of the wafer is patterned to provide an alignment pattern for the purpose of enabling subsequent provision of holes by drilling.

11. The method as claimed in claim 8, further comprising thermally oxidizing the entire wafer so as to create a protective layer before the drilling.

12. The method as claimed in claim 11, comprising etching away the protective layer after drilling.

13. The method as claimed in claim 12, comprising rinsing away any remaining particles that may still be present on the micro structures;

14. The method as claimed in claim 13, comprising growing an oxide on the entire wafer to a desired thickness; and dicing the wafer.

15. The method of claim 8, wherein said micro mechanical structure is made from a semi-conductor material, e.g. silicon.

16. The method of claim 8, wherein said drilling is performed by any of Drilling, Laser drilling, Ultra sonic drilling, Water or sand power blasting, Electro Discharge Machining (EDM micromachining).

17. The method of claim 8, wherein the structural components for a large number of devices are made on one wafer of material at the same time, and wherein said drilling is carried out on one wafer at a time, preferably using Computerized Numerical Control (CNC) machines with precise alignment through automated pattern recognition and semiconductor standardized cassette to cassette wafer handling using robot based load/unloading stations.

18. The method of claim 8, wherein a hard ware glass plate mask is used for transferring patterns.

19. The method of claim 8, wherein said micro structures are pillars and channels.

20. The method of claim 8, wherein said first oxide layer is thick enough to be usable as a DRIE mask for the further processing of the wafer, suitably having a thickness of 0.5-4 μm.

21. A method of making a microfluidic device having inlet and/or outlet connections for fluids, the method comprising:
growing a first oxide layer on a starting semiconductor, e.g. silicon wafer;
transferring a pattern defining the functional structures of the microfluidic device is transferred to the oxide by lithographic and etching methods;
optionally patterning also the back side of the wafer to provide an alignment pattern for the purpose of enabling subsequent provision of holes by drilling;
etching through the mask so as to create the structures forming the micro fluidic chip device, and said alignment pattern;
thermally oxidizing of the entire wafer is performed so as to create a protective layer;
drilling holes from the back side of the wafer using the alignment pattern to match the holes to said micro structures;
etching away the protective layer;
rinsing away any remaining particles that may still be present on the micro structures;
growing an oxide on the entire wafer to a desired thickness; and
dicing the wafer.

22. The method as claimed in claim 21, wherein the etching to create structures suitably is a silicon DRIE process.

23. The method as claimed in claim 21, wherein the etching to create alignment pattern is suitably an oxide etch process.

24. The method as claimed in claim 21, wherein the thermal oxidation is typically in wet (or dry) O₂ atmosphere, at 800-1200° C., in a standard semiconductor oxidation oven, to a thickness of 0.5-4 μm

25. The method as claimed in claim 21, wherein the thickness of the final oxide is 500-1000 Å.

26. The method as claimed in claim 21, wherein a hard ware glass plate mask is used for transferring pattern

27. The method as claimed in claim 21, wherein said micro structures are pillars and channels.

28. The method as claimed in claim 21, wherein said first oxide layer is thick enough to be usable as a DRIE mask for the further processing of the wafer, suitably having a thickness of 0.5-4 μm.

29. A method of making a fluid communication channel to a micro mechanical structure provided on a front side of a device, comprising
making the required structural components by lithographic and etching processes on said front side;
providing a lid for covering said structural components;
drilling holes in said lid in a pattern matching said structural components;
attaching said lid on said front side of said device, thereby providing inlets and/or outlets to and/or from said structural components.

30. A micro fluidic device comprising structural components on one side of a substrate and at least one inlet and/or outlet to/from said components opening on the back side of said substrate.

31. A micro fluidic device comprising structural components on one side of a substrate, a lid covering the components, and at least one inlet and/or outlet to/from said components provide through said lid.
